(19) United States
(12) Patent Application Publication
(10) Pub. No.: US 2016/0113136 A1
(43) Pub. Date: Apr. 21, 2016

(54) CASE IN WHICH ELECTRICAL PARTS ARE ACCOMMODATED AND ELECTRONIC DEVICE HAVING THE SAME

(71) Applicant: SAMSUNG ELECTRONICS CO., LTD., Suwon-si (KR)

(72) Inventors: Bongsu SHIN, Seoul (KR); Joonyong Park, Suwon-si (KR); Dongouk KIM, Pyeongtaek-si (KR); Jihyun BAE, Seoul (KR); Jong Girl OK, Seoul (KR); Ilsun YOON, Seongnam-si (KR); Sunghoon LEE, Seoul (KR); Jaeseung CHUNG, Suwon-si (KR); Sukgyu HAHM, Gyeongju-si (KR)

(73) Assignee: SAMSUNG ELECTRONICS CO., LTD., Suwon-si (KR)

(21) Appl. No.: 14/918,663

(22) Filed: Oct. 21, 2015

(30) Foreign Application Priority Data
Oct. 21, 2014 (KR) 10-2014-0142769

(51) Int. Cl. H05K 5/06

(52) U.S. Cl. CPC H05K 5/06

(57) ABSTRACT

Provided is a case accommodating at least one electrical part and including: a first panel and a second panel coupled to each other, a space between the first and the second panels accommodating the at least one electrical part; a first facing surface provided along surrounding edges of an area, the area being exposed when the second panel is separated from the first panel; a second facing surface corresponding to the first facing surface and provided on the second panel; and hydrophobic pattern formed on at least one of the first and the second facing surfaces.

### CROSS-REFERENCE TO RELATED APPLICATION

This application claims priority from Korean Patent Application No. 10-2014-0142769, filed on Oct. 21, 2014, in the Korean Intellectual Property Office, the disclosure of which is incorporated herein by reference in its entirety.

### BACKGROUND

1. Field

Apparatuses consistent with exemplary embodiments relate to cases in which electrical parts are accommodated, and electronic devices having the same.

2. Description of the Related Art

Electronic devices each include a case in which one or more electrical parts are accommodated. When one or more electrical parts are exposed to moisture, they may be damaged by an electrical short. Thus, a waterproof structure is applied to the case. For example, in a portable electronic device such as a mobile phone, an opening is formed in a portion of the case so that a battery may be changed, and the opening is covered using a cover after the battery is mounted. In order to prevent penetration of moisture through the opening, a rubber packing is installed along edges of the opening, and the rubber packing is pressed using the cover so that the waterproof structure may be employed.

A general waterproof structure using the rubber packing may lose a waterproof function in water having a depth of 10 m or higher or under high dynamic pressure conditions, as an extreme example. Also, the waterproof function may be lost by a change in properties of the rubber packing over time.

Also, precise position alignment between the case, the cover, and the rubber packing is required so that the rubber packing can be pressed between the case and the cover when the case and the cover are coupled to each other. If an error occurs in the position alignment, the waterproof function may be lost. Thus, the waterproof structure that employs the rubber packing has a complicated assembly process, and a structure for position alignment should be provided on the case and the cover and thus, the structural arrangement of the electrical parts may also be complicated.

### SUMMARY

Provided are cases that may maintain a stable waterproof function and electronic devices having the same.

Additional aspects will be set forth in part in the description which follows and, in part, will be apparent from the description, or may be learned by practice of the presented exemplary embodiments.

According to an aspect of an exemplary embodiment, a case in which at least one electrical part is accommodated, includes: a first panel and a second panel that are coupled to each other and form a space in which the at least one electrical part is accommodated; a first facing surface that is formed on the first panel by surrounding edges of an area opened when the second panel is separated from the first panel; a second facing surface that is formed on the second panel to correspond to the first facing surface; and hydrophobic fine uneven patterns formed on at least one of the first and second facing surfaces.

The hydrophobic fine uneven patterns may include nanofibers.

The hydrophobic fine uneven patterns may be perpendicular to the first and second facing surfaces.

The hydrophobic fine uneven patterns may be inclined with respect to the first and second facing surfaces. The hydrophobic fine uneven patterns may be inclined toward an outside with respect to the first and second facing surfaces.

The case may further include an elastic sealing member interposed between the first and second facing surfaces, wherein the hydrophobic fine uneven patterns may be formed in at least one of an inside area and an outside area based on the elastic sealing member. First and second grooves into which the elastic sealing member is seated, may be formed in the first and second facing surfaces.

The case may further include first and second waterproof members each having one surface on which the hydrophobic fine uneven patterns are formed, the first and second waterproof members being attached onto the first and second facing surfaces.

The case may further include: a first sealing member disposed on the first facing surface; and a second sealing member disposed on the second facing surface to correspond to the first sealing member, wherein the hydrophobic fine uneven patterns are formed on facing surfaces of the first and second sealing members. First and second grooves into which the first and second sealing members are seated, may be formed in the first and second facing surfaces. The case may further include first and second waterproof members each having one surface on which the hydrophobic fine uneven patterns are formed, the first and second waterproof members being attached onto facing faces of the first and second sealing members.

According to an aspect of another exemplary embodiment, an electronic device includes: the case; and at least one electrical part accommodated in the case.

According to an aspect of another exemplary embodiment, there is provided a case accommodating at least one electrical part, the case including: a first panel and a second panel coupled to each other, a space between the first and the second panels accommodating the at least one electrical part; a first facing surface provided along surrounding edges of an area, the area being exposed when the second panel is separated from the first panel; a second facing surface corresponding to the first facing surface and provided on the second panel; and a hydrophobic pattern formed on at least one of the first and the second facing surfaces.

The hydrophobic pattern may include a nanofiber.

The hydrophobic pattern may protrude perpendicularly from the first and the second facing surfaces.

The hydrophobic pattern may be inclined with respect to the first and the second facing surfaces.

The hydrophobic pattern may be inclined toward an exterior of the case.

The case may further include an elastic sealing member interposed between the first and the second facing surfaces, wherein the hydrophobic pattern may be provided in at least one of an inner area and an outer area with respect to the elastic sealing member.

The first and the second facing surfaces may include a first groove and a second groove, respectively, configured to accommodate the elastic sealing member.

The case may further include a first waterproof member and a second waterproof member, the first and the second waterproof members respectively comprising a surface on which the hydrophobic pattern is formed, wherein the first and the second waterproof members may be attached onto the first and the second facing surfaces, respectively.

The case may further include: a first sealing member provided on the first facing surface; and a second sealing member corresponding to the first sealing member and provided on the second facing surface, wherein the hydrophobic pattern is formed on respective facing surfaces of the first and the second sealing members.

### BRIEF DESCRIPTION OF THE DRAWINGS

These and/or other aspects will become apparent and more readily appreciated from the following description of the exemplary embodiments, taken in conjunction with the accompanying drawings in which:

FIG. 1 is a partial exploded perspective view of an electronic device according to an exemplary embodiment;

FIG. 2 is a cross-sectional view of a waterproof structure according to an exemplary embodiment;

FIG. 3 is a view of a state in which water penetrates into a gap d in the waterproof structure illustrated in FIG. 2;

FIG. 4 is a graph showing a simulation result of the relationship between the size of the gap d and a height H of water head when hydrophobic fine uneven patterns are formed;

FIG. 5 is a graph showing a simulation result of the relationship between the size of the gap d and a capillary pressure ΔP caused by a difference between an advancing contact angle θₐ and a receding contact angle θᵣ;

FIG. 6 is a graph showing a simulation result of the relationship between the size of the gap d and the capillary pressure ΔP when the height h of a unit pattern is 100 nm;

FIG. 7 is a graph showing a simulation result of the relationship between the size of the gap d and the capillary pressure ΔP when the height h of the unit pattern is 150 nm;

FIG. 8 is a graph showing a simulation result of the relationship between the size of the gap d and the capillary pressure ΔP when the height h of the unit pattern is 200 nm;

FIG. 9 is a cross-sectional view of a waterproof structure according to another exemplary embodiment;

FIG. 10 is a view of a state in which water penetrates into the gap d in the waterproof structure illustrated in FIG. 9;

FIG. 11 is a cross-sectional view of a waterproof structure according to another exemplary embodiment;

FIG. 12 is a partial exploded perspective view of an electronic device that employs a waterproof structure, according to another exemplary embodiment;

FIG. 13 is a cross-sectional view of a waterproof structure according to another exemplary embodiment; and

FIGS. 14A and 14B are cross-sectional views of a waterproof structure according to other exemplary embodiments.

### DETAILED DESCRIPTION

Reference will now be made in detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain aspects. In the drawings, the sizes of elements may be exaggerated for clarity and convenience of explanation. As used herein, the term “and/or” includes any and all combinations of one or more of the associated listed items. Expressions such as “at least one of,” when preceding a list of elements, modify the entire list of elements and do not modify the individual elements of the list.

Degree of protection provided by enclosures (IP code) is stipulated in Korea industrial standard (KS). IP code is represented by IP12, for example. Here, ‘1’ is a first characteristic number that represents a degree of protection (dustproof degree) against dust, for example, and ‘2’ is a second characteristic number that represents a degree of protection (waterproof degree) against moisture, for example. Hereinafter, the dustproof degree and the waterproof degree will be briefly described.

<Dustproof Degree>

0: non-protected

1: protected against objects of 50 mm diameter and greater

2: protected against objects of 12.5 mm diameter and greater

3: protected against objects of 2.5 mm diameter and greater

4: protected against objects of 1.0 mm diameter and greater

5: dust-protected

6: dust-tight

<Waterproof Degree>

0: non-protected

1: protected against vertically falling waterdrops

2: protected against vertically falling waterdrops when enclosure tilted up to 15°

3: protected against water sprayed at an angle up to 60°

4: protected against splashing water from any direction

5: protected against water jets in any direction

6: protected against powered water jets from any direction

7: protected against the effects of 15 cm˜1 m immersion in water for 30 minute

8: protected against continuous immersion in water and water pressure applied in a state of continuous immersion

For example, IP67 represents that an article is completely protected against dust and maintains a waterproof function for 30 minutes in the depth of water of 1 m.

An electronic device, in particular, a portable mobile device, for example, communication terminal equipment, a game device, a multimedia device, a portable computer, and an image capturing device, requires a more stable waterproof function due to characteristics of a usage environment.

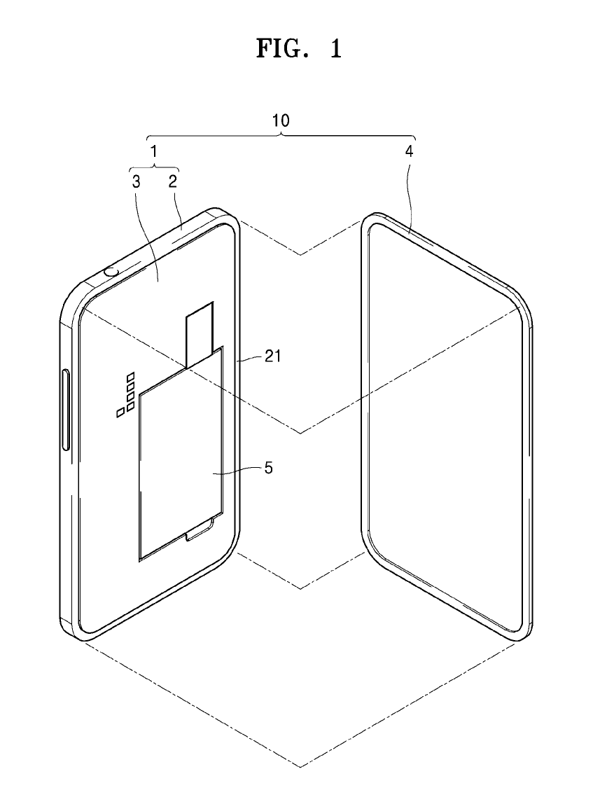

FIG. 1 is a partial exploded perspective view of an electronic device according to an exemplary embodiment. The electronic device according to the present embodiment is portable communication terminal equipment, a so-called mobile phone. Referring to FIG. 1, the mobile phone includes a case 10 which forms an exterior and in which one or more electrical parts, for example, a battery 5, is accommodated. The case 10 may have a shape in which one or more parts are coupled to each other. For example, the case 10 may include a main case 1 in which a main board (not shown) for performing a function of the mobile phone, a display (not shown), and a camera (not shown) are accommodated, and a rear panel 4 that is attached to or detached from the main case 10 so as to exchange the battery 5. Although not shown in detail, the main case 1 may include a plurality of panels, such as a front panel 2, and an intermediate panel 3 that is coupled to the front panel 2 and forms a space in which the main board (not shown), the display (not shown), and the camera (not shown) will be accommodated. The rear panel 4 may be coupled to the front panel 2, for example, and may protect the electrical parts in the case 10 against penetration of moisture.

Hereinafter, exemplary embodiments of a structure for waterproofing will be described in detail. The structure for waterproofing that will be described later may be applied to at least one of a pair of panel pairs that are coupled to each other and constitute the case 10. Hereinafter, a waterproof structure applied between the front panel 2 and the rear panel 4 will be described as an example. The waterproof structure that will be described later may also be applied between the front panel 2 and the intermediate panel 3 or may also be applied between the intermediate panel 3 and the rear panel 4 as needed. Hereinafter, the front panel 2 is referred to as a first panel 2, and the rear panel is referred to as a second panel 4.

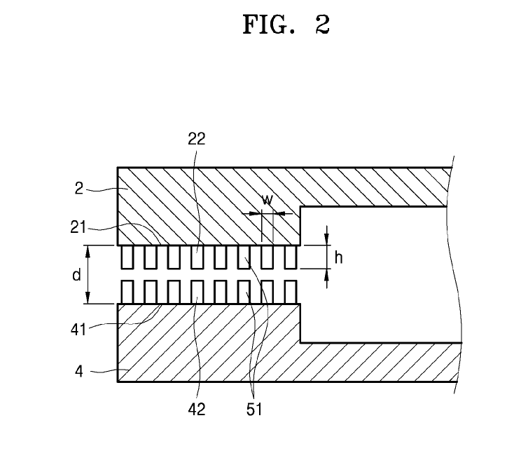

Referring to FIG. 1, the first panel 2 includes a first facing surface 21 having a shape in which the first facing surface 21 surrounds edges of an area opened when the second panel 4 is separated from the first panel 2. The second panel 4 may be coupled to the first panel 2 using a screw coupling method or a snap-fit coupling method so that the first facing surface 21 and a second facing surface (see 41 of FIG. 2) may face each other.

FIG. 2 is a cross-sectional view of a waterproof structure according to an exemplary embodiment. Referring to FIG. 2, even when the first panel 2 and the second panel 4 are coupled to each other, a gap d may be formed between the first and second facing surfaces 21 and 41. Moisture may penetrate into the case 10 through the gap d. The waterproof structure may be provided on the first and second facing surfaces 21 and 41. In the waterproof structure according to the present embodiment, hydrophobic fine uneven patterns 22 and 42 may be formed in the first and second facing surfaces 21 and 41, respectively. The hydrophobic fine uneven patterns 22 and 42 include a plurality of unit patterns 51 each having a height h and a width w, for example. The plurality of unit patterns 51 may be nanofibers, such as nanowires, nanotubes, or nanorods. The height h and the width w of each of the unit patterns 51 may be about several to several hundreds of nanometers, for example. The nanofibers may be manufactured using various methods, for example, a vapor deposition method or a vapor growth method, according to a material used to form the nanofibers. Also, each unit pattern 51 may be formed of a hydrophobic material. Each unit pattern 51 may have a shape in which the hydrophobic material having low surface energy is coated on a hydrophilic material.

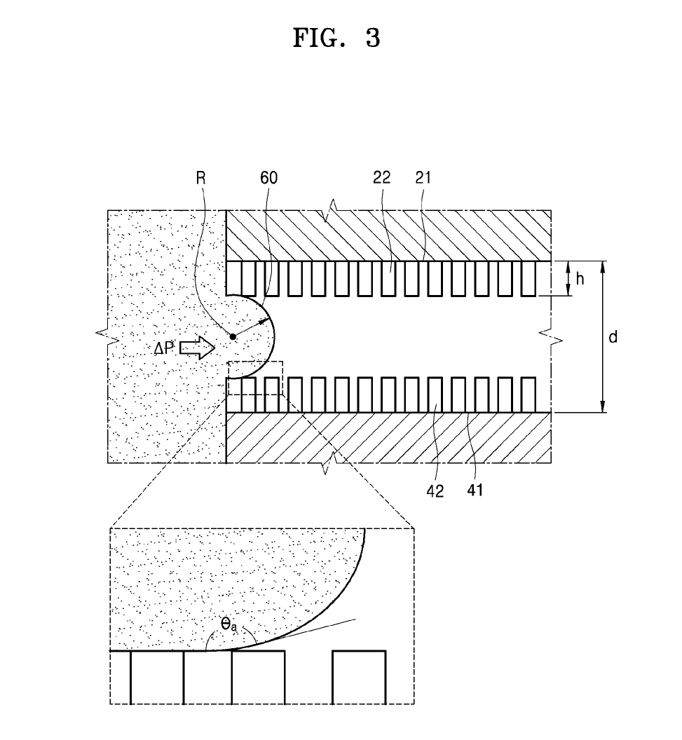

FIG. 3 is a view of a state in which water penetrates into the gap d in the waterproof structure illustrated in FIG. 2. Referring to FIG. 3, a capillary pressure ΔP is applied to the gap d through a droplet 60. The droplet 60 has an advancing contact angle θₐ with respect to the hydrophobic fine uneven patterns 22 and 42. Here, when surface energy of water is γ, a radius of the droplet is R, density of water is ρ, gravity acceleration is g and a height of water head is H,

$$Δ P = γ \frac{1}{R} = - γ \frac{2 cos {θ}_{a}}{d - 2 h} < ρ gH \\ H > - γ \frac{2 cos {θ}_{a}}{ρ g ( d - 2 h )} \qquad ( 1 )$$

For example, when γ=0.072 N/m, d=1 μm, h=200 nm, θₐ=130°, ρ=1000 Kg/m³ and g=9.8 m/s², H is about 18 m so that higher dustproof/waterproof performance than a degree of IP67 may be obtained. Theoretically, the waterproof performance may be maintained at H of about 18 m regardless of time.

For comparison, when a hydrophobic thin film coating layer (not shown) is formed on the first and second facing surfaces 21 and 41, instead of the hydrophobic fine uneven patterns 51, if the advancing contact angle is θₐ₁, a height H1 of the water head is obtained using the following equation 2.

$$H 1 > - γ \frac{2 cos {θ}_{a 1}}{ρ gd} \qquad ( 2 )$$

Since θₐ>θₐ₁>90° and a denominator of Equation 1 is smaller than a denominator of Equation 2, H>H1, and further improved waterproof function may be obtained when the hydrophobic fine uneven patterns 22 and 42 are formed. That is, a larger capillary pressure is required so that the droplet 60 may penetrate into the gap d in which the hydrophobic fine uneven patterns 22 and 42 are formed. For example, when γ=0.072 N/m, d=1 μm, h=200 nm, θₐ₁=130°, ρ=1000 Kg/m³ and g=9.8 m/s², H1 is about 9 m, and if θₐ₁=100° in the same condition, H1 is about 3 m so that the waterproof performance is lowered compared to a case where the hydrophobic fine uneven patterns 22 and 42 are formed.

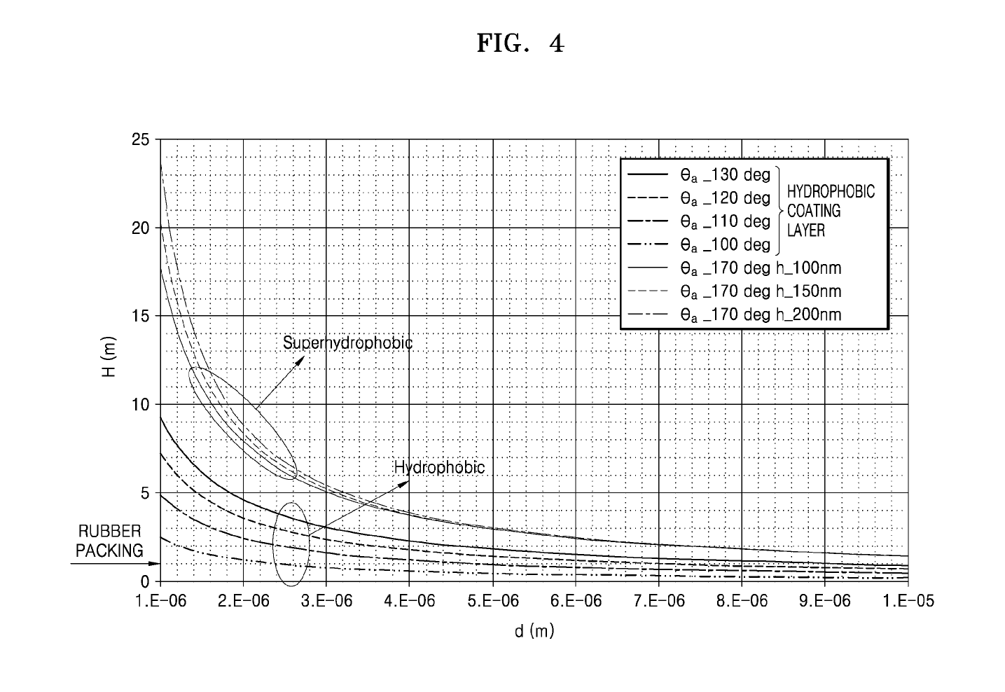

FIG. 4 is a graph showing a simulation result of the relationship between the size of the gap d and the height H of water head when the hydrophobic fine uneven patterns 22 and 42 are formed. Referring to FIG. 4, when the hydrophobic fine uneven patterns 22 and 42 are formed, higher waterproof performance with respect to the gap d having almost all sizes are shown compared to a waterproof structure that employs a rubber packing according to the related art. Also, when the hydrophobic fine uneven patterns 22 and 42 are formed, higher waterproof performance is shown compared to a case where a hydrophobic coating layer is formed. That is, when the hydrophobic fine uneven patterns 22 and 42 are formed, if the gap d is the same, the waterproof function may be maintained even in water having a larger depth compared to the case where the hydrophobic coating layer is formed. This is because, when the hydrophobic fine uneven patterns 22 and 42 are formed, a very large advancing contact angle θₐ that corresponds to a superhydrophobic area may be obtained.

A contact angle includes an apparent contact angle that is a static contact angle in a state in which the droplet is in contact with a solid and an interface of droplet constitutes thermodynamic equilibrium, and an advancing contact angle θₐ and a receding contact angle θᵣ that are dynamic contact angles when thermodynamic equilibrium is broken. The advancing contact angle refers to a contact angle immediately before three-phase interfaces having solid, liquid, and gaseous phases move when liquid is slowly supplied to the droplet in the thermodynamic equilibrium state. The receding contact angle refers to a contact angle immediately before the three-phase interfaces having solid, liquid, and gaseous phases move when liquid is slowly drawn from the droplet in the thermodynamic equilibrium state.

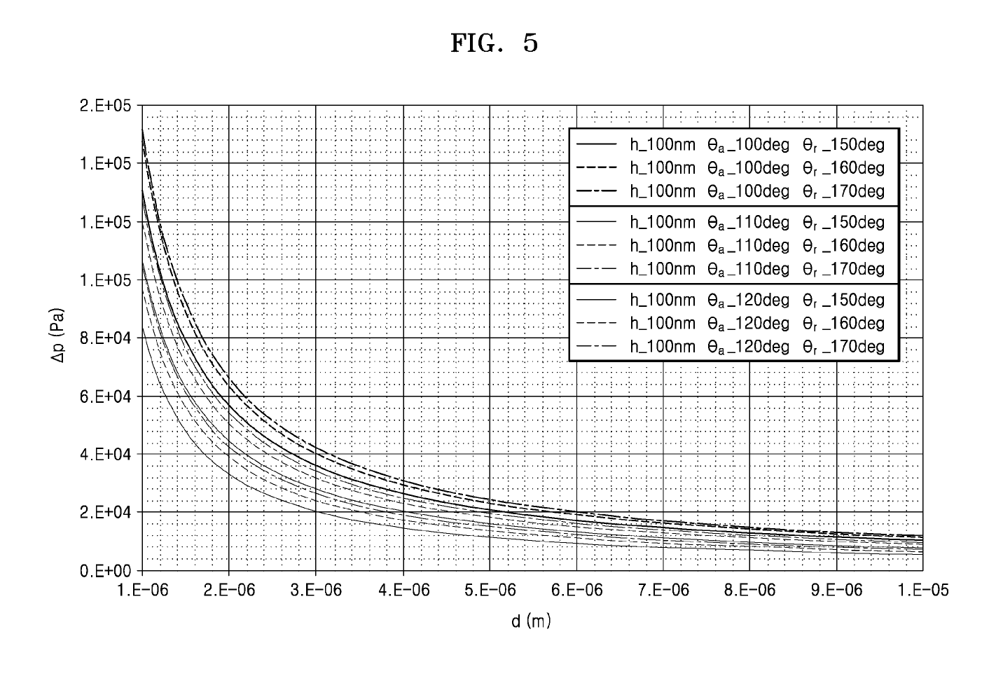

FIG. 5 is a graph showing a simulation result of the relationship between the size of the gap d and the capillary pressure ΔP caused by a difference between the advancing contact angle θₐ and the receding contact angle θᵣ. Referring to FIG. 5, as the difference between the advancing contact angle θₐ and the receding contact angle θᵣ increases, higher waterproof performance may be obtained in the same gap d.

In general, the difference between the advancing contact angle θₐ and the receding contact angle θᵣ increases as non-uniformity of surface energy and physical roughness of a solid surface increase. Non-uniformity of the surface energy and physical roughness of a solid surface are increased by the hydrophobic fine uneven patterns 22 and 42 so that the difference between the advancing contact angle θₐ and the receding contact angle θᵣ increases further compared to the case where the hydrophobic coating layer is formed and higher waterproof performance may be obtained.

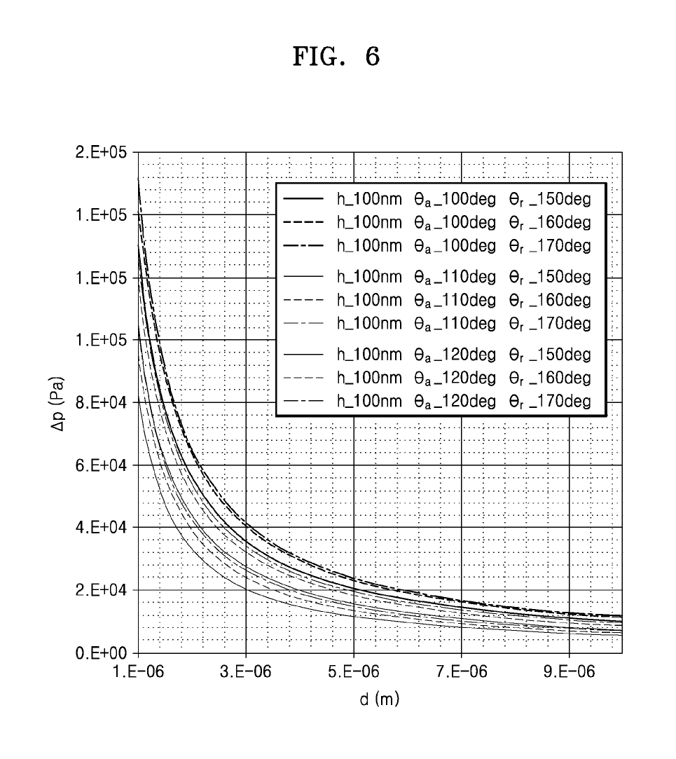

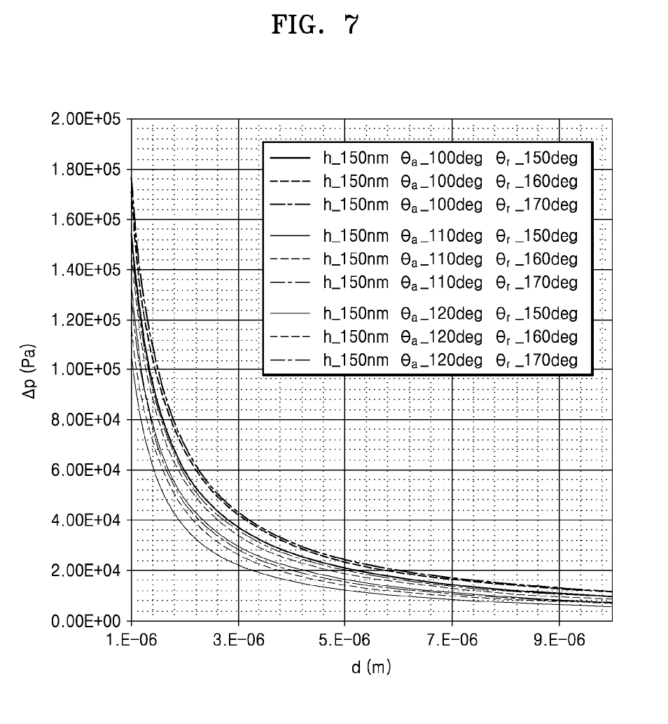

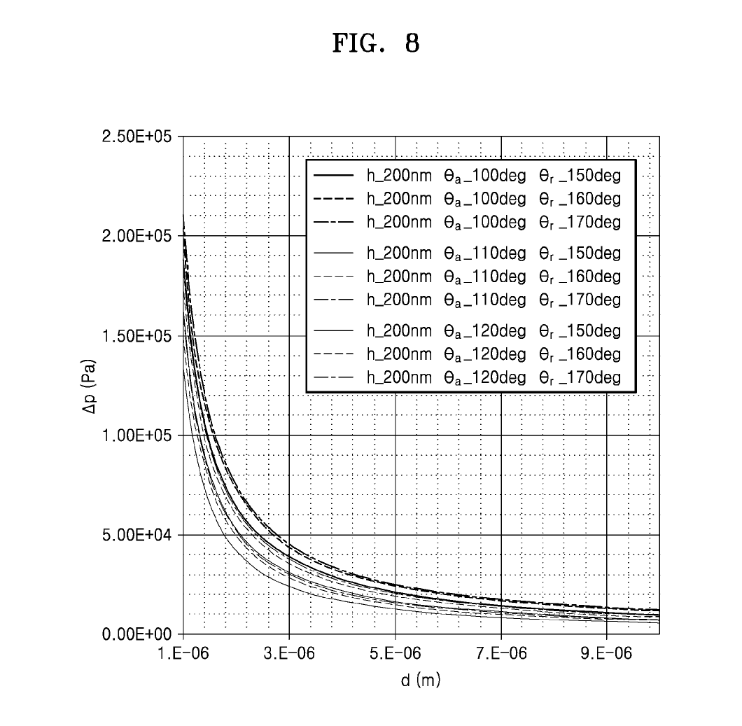

FIG. 6 is a graph showing a simulation result of the relationship between the size of the gap d and the capillary pressure ΔP when the height h of the unit pattern 51 is 100 nm. FIG. 7 is a graph showing a simulation result of the relationship between the size of the gap d and the capillary pressure ΔP when the height h of the unit pattern 51 is 150 nm. FIG. 8 is a graph showing a simulation result of the relationship between the size of the gap d and the capillary pressure ΔP when the height h of the unit pattern 51 is 200 nm.

Referring to FIGS. 6 through 8, higher waterproof performance is shown as the height h of the unit pattern 51 increases.

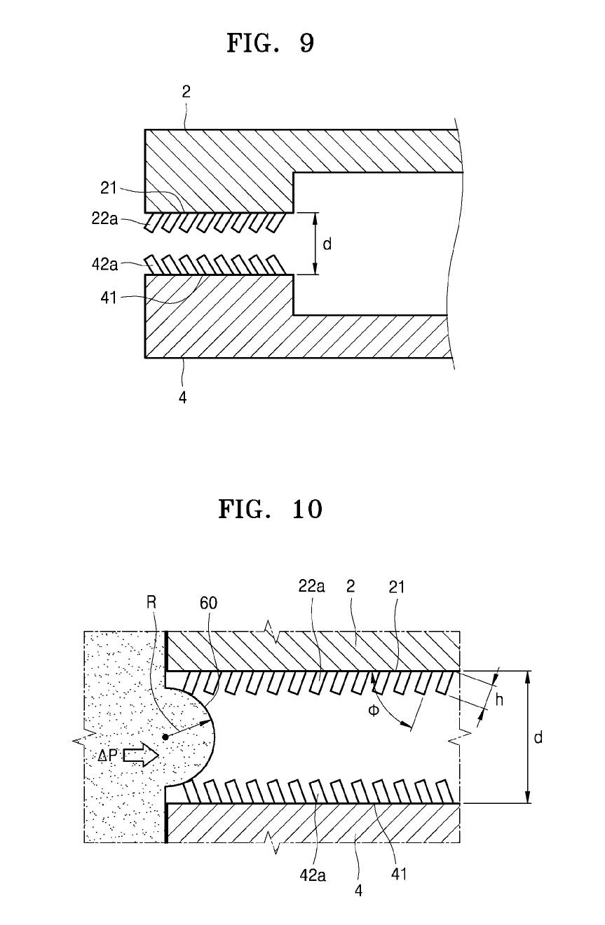

FIG. 9 is a cross-sectional view of a waterproof structure according to another exemplary embodiment. FIG. 10 is a view of a state in which water penetrates into the gap d in the waterproof structure illustrated in FIG. 9. Referring to FIGS. 9 and 10, hydrophobic fine uneven patterns 22a and 42a that are inclined toward the outside are formed on the first and second facing surfaces 21 and 41. In the hydrophobic fine uneven patterns 22a and 42a having the inclined shape, the advancing contact angle of the droplet 60 is approximately 180°.

When the capillary pressure applied to the gap d through the droplet 60 is ΔP, the surface energy of water is γ, a radius of the droplet 60 is R, density of water is ρ, gravity acceleration is g and a height of water head is H3,

$$Δ P = γ \frac{1}{R} = γ \frac{2 sin φ}{d - 2 h sin φ} < ρ gH 3 \\ H 3 > γ \frac{2 sin φ}{ρ g ( d - 2 h sin φ )} \qquad ( 3 )$$

When γ=0.072 N/m, d=1 μm, h=200 nm, ρ=1000 Kg/m³, g=9.8 m/s² and φ=60°, H3 is about 18 m so that almost equivalent waterproof performance to that of the waterproof structure illustrated in FIGS. 2 and 3 may be obtained.

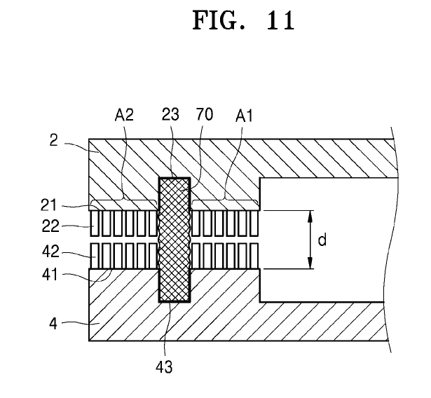

FIG. 11 is a cross-sectional view of a waterproof structure according to another exemplary embodiment. Referring to FIG. 11, a sealing member 70 is interposed between the first and second facing surfaces 21 and 41. The sealing member 70 may be formed of a material having a waterproof property and elasticity, for example, a rubber material. When the first and second panels 2 and 4 are coupled to each other, the sealing member 70 is elastically compressed so that a waterproof and dustproof structure may be formed.

A first groove 23 recessed from the first facing surface 21 may be formed in the first panel 2, and a second groove 43 recessed from the second facing surface 41 may be formed in the second panel 4. The sealing member 70 may be inserted into the first and second grooves 23 and 43. The first and second grooves 23 and 43 may be formed to face each other and may serve as seating grooves on which the sealing member 70 is seated and simultaneously may serve as position determining grooves of the sealing member 70. When the first panel 2 and the second panel 4 are coupled to each other using a fastening member (not shown), for example, a screw, in a state in which the sealing member 70 is inserted into the first groove 23 or the second groove 43, the sealing member 70 is compressed in the first and second grooves 23 and 43 and blocks penetration of moisture and dust through the gap d.

The hydrophobic fine uneven patterns 22 and 42 are formed on an inside area A1 based on the sealing member 70. Thus, moisture that passes through the waterproof structure using the sealing member 70 may be blocked by the hydrophobic fine uneven patterns 22 and 42. The hydrophobic fine uneven patterns 22 and 42 may be formed in an outside area A2 based on the sealing member 70 or may also be formed in both the inside area A1 and the outside area A2 based on the sealing member 70. The hydrophobic fine uneven patterns 22a and 42a having the inclined shape may also be formed in the inside area A1 and/or the outside area A2, instead of the hydrophobic fine uneven patterns 22 and 42.

As described above, in the waterproof structure that employs the hydrophobic fine uneven patterns 22 and 42 or the inclined hydrophobic fine uneven patterns 22a and 42a, a superhydrophobic property is implemented in the gap d using a hydrophobic material so that high and stable waterproof performance may be implemented. Also, since no high position precision is required when the first and second panels 2 and 4 are coupled to each other, assembling costs may be reduced, and parts costs may also be reduced.

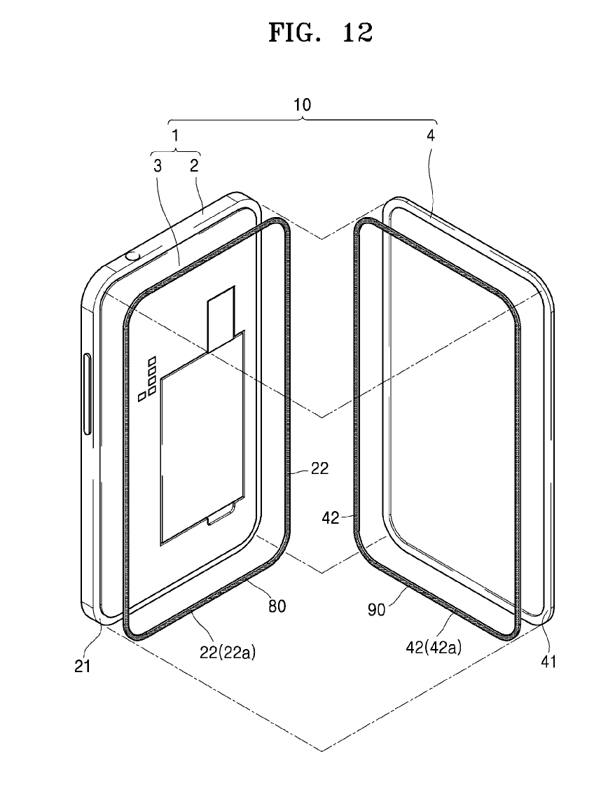

FIG. 12 is a partial exploded perspective view of an electronic device that employs a waterproof structure, according to another exemplary embodiment. Referring to FIG. 12, first and second waterproof members 80 and 90 are attached to the first facing surface 21 of the first panel 2 and the second facing surface 41 of the second panel 4, respectively. The first waterproof member 80 has a shape of a band that surrounds edges of the opened area of the first panel 2. Hydrophobic fine uneven patterns 22 are formed on one surface of the first waterproof member 80. The second waterproof member 90 has a shape correspond to that of the first waterproof member 80. Hydrophobic fine uneven patterns 42 are formed on one surface of the second waterproof member 90. Through this configuration, the same effects as those of the waterproof structure illustrated in FIGS. 2 and 3 may be achieved. The hydrophobic fine uneven patterns 22a and 42a having the inclined shape may also be formed on the first and second waterproof members 80 and 90, instead of the hydrophobic fine uneven patterns 22 and 42. In the embodiment shown in FIG. 11, the hydrophobic fine uneven patterns 22 and 42 disposed in the inside area A1 and/or the outside area A2 of the sealing member 70 may be replaced with the first and second waterproof members 80 and 90.

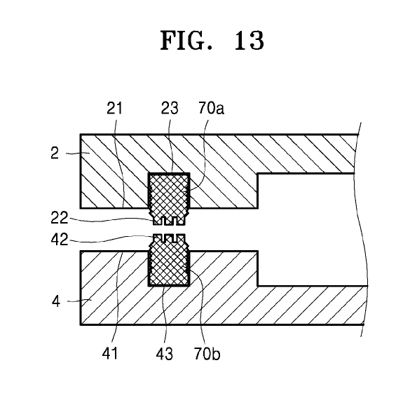

FIG. 13 is a cross-sectional view of a waterproof structure according to another exemplary embodiment. Referring to FIG. 13, first and second sealing members 70a and 70b are disposed on the first and second facing surfaces 21 and 41. The first and second sealing members 70a and 70b may be formed of a material having a waterproof property and elasticity, for example, a rubber material. The first and second sealing members 70a and 70b are compressed with respect to each other when the first and second panels 2 and 4 are coupled to each other, so that the dustproof and waterproof structure may be formed. The first groove 23 recessed from the first facing surface 21 may be formed in the first panel 2, and the second groove 43 recessed from the second facing surface 41 may be formed in the second panel 4. The first and second sealing members 70a and 70b are inserted into the first and second grooves 23 and 43, respectively. The first and second grooves 23 and 43 are formed to face each other and serve as seating grooves on which the first and second sealing members 70a and 70b are seated. When the first panel 2 and the second panel 4 are coupled to each other using the fastening member (not shown), for example, a screw, in a state in which the first and second sealing members 70a and 70b are inserted into the first groove 23 or the second groove 43, the first and second sealing members 70a and 70b are compressed in the first and second grooves 23 and 42 so that penetration of moisture from the outside may be blocked.

Due to various causes, the first and second sealing members 70a and 70b may not be compressed with respect to each other. Then, a gap may be formed between the first and second sealing members 70a and 70b, and the gap is a penetration path of moisture. In the waterproof structure according to the present embodiment, the hydrophobic fine uneven patterns 22 and 42 are formed on facing surfaces of the first and second sealing members 70a and 70b. Thus, penetration of moisture through the gap between the first and second sealing members 70a and 70b may be prevented. The hydrophobic fine uneven patterns 22 and 42 formed on the facing surfaces of the first and second sealing members 70a and 70b may be replaced with the first and second waterproof members 80 and 90 of FIG. 12. That is, the first and second waterproof members 80 and 90 of FIG. 12 may be attached to the facing surfaces of the first and second sealing members 70a and 70b.

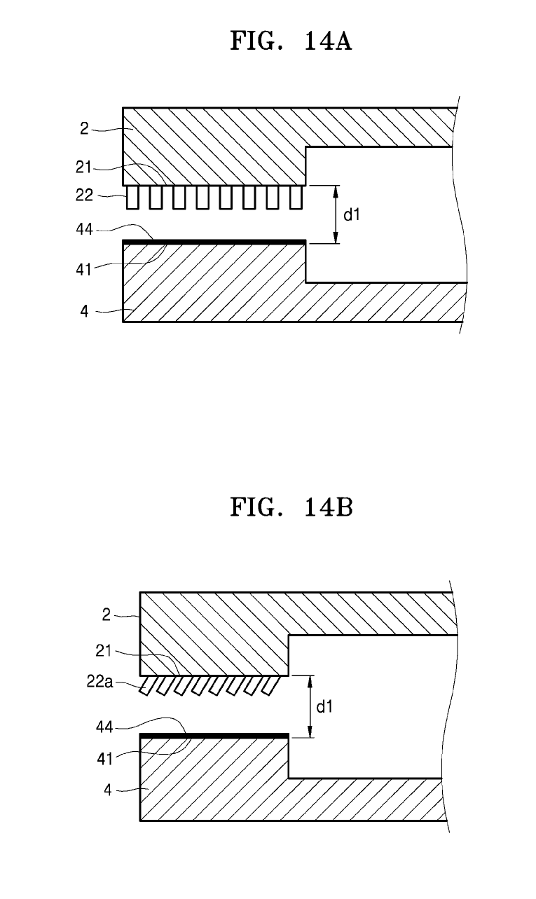

In the above-described embodiments, hydrophobic uneven patterns are formed on the first and second facing surfaces 21 and 41. However, the scope of the inventive concept is not limited thereto. The hydrophobic uneven patterns may also be formed on either of the first and second facing surfaces 21 and 42. FIGS. 14A and 14B are cross-sectional views of a waterproof structure according to other exemplary embodiments. Referring to FIG. 14A, hydrophobic uneven patterns 22 are formed on the first facing surface 21. Referring to FIG. 14B, hydrophobic uneven patterns 22a having an inclined shape are formed on the first facing surface 21. In both cases, the second facing surface 41 is a hydrophobic surface. The hydrophobic surface may be implemented when a hydrophobic coating layer 44 is formed on the second facing surface 41, for example. Even through the waterproof structure, the superhydrophobic property may be implemented in a gap d1.

Embodiments of the waterproof structures illustrated in FIGS. 14A and 14B may be applied to the embodiment of FIG. 11. That is, no hydrophobic patterns 42 may be formed on the second facing surface 41 in FIG. 11, and the hydrophobic coating layer 44 may be formed on the second facing surface 41, instead of the hydrophobic patterns 42.

It should be understood that the exemplary embodiments described therein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims.

What is claimed is:

1. A case accommodating at least one electrical part, the case comprising:
a first panel and a second panel coupled to each other, a space between the first and the second panels accommodating the at least one electrical part;
a first facing surface provided along surrounding edges of an area, the area being exposed when the second panel is separated from the first panel;
a second facing surface corresponding to the first facing surface and provided on the second panel; and
a hydrophobic pattern formed on at least one of the first and the second facing surfaces.

2. The case of claim 1, wherein the hydrophobic pattern comprises a nanofiber.

3. The case of claim 1, wherein the hydrophobic pattern protrudes perpendicularly from the first and the second facing surfaces.

4. The case of claim 1, wherein the hydrophobic pattern is inclined with respect to the first and the second facing surfaces.

5. The case of claim 4, wherein the hydrophobic pattern is inclined toward an exterior of the case.

6. The case of claim 1, further comprising an elastic sealing member interposed between the first and the second facing surfaces,
wherein the hydrophobic pattern is provided in at least one of an inner area and an outer area with respect to the elastic sealing member.

7. The case of claim 6, wherein the first and the second facing surfaces comprise a first groove and a second groove, respectively, configured to accommodate the elastic sealing member.

8. The case of claim 1, further comprising a first waterproof member and a second waterproof member, the first and the second waterproof members respectively comprising a surface on which the hydrophobic pattern is formed,
wherein the first and the second waterproof members are attached onto the first and the second facing surfaces, respectively.

9. The case of claim 1, further comprising:
a first sealing member provided on the first facing surface; and
a second sealing member corresponding to the first sealing member and provided on the second facing surface,
wherein the hydrophobic pattern is formed on respective facing surfaces of the first and the second sealing members.

10. The case of claim 9, wherein the first and second facing surfaces comprise a first groove and a second groove, respectively, configured to accommodate respective first and second sealing members.

11. The case of claim 9, further comprising a first waterproof member and a second waterproof member, the first and the second waterproof members respectively comprising a surface on which the hydrophobic pattern is formed,
wherein the first and the second waterproof members are attached onto the first and the second facing surfaces, respectively.

12. An electronic device comprising:
the case of claim 1; and
at least one electrical part accommodated in the case.

13. The electronic device of claim 12, wherein the hydrophobic pattern protrudes perpendicularly from the first and the second facing surfaces.

14. The electronic device of claim 12, wherein the hydrophobic pattern is inclined with respect to the first and the second facing surfaces.

15. The electronic device of claim 12, further comprising an elastic sealing member interposed between the first and the second facing surfaces,
wherein the hydrophobic pattern is provided in at least one of an inner area and an outer area with respect to the elastic sealing member.

16. The electronic device of claim 15, wherein the first and the second facing surfaces comprise a first groove and a second groove ,respectively, configured to accommodate the elastic sealing member.

17. The electronic device of claim 12, further comprising a first waterproof member and a second waterproof member, the first and the second waterproof members respectively comprising a surface on which the hydrophobic pattern is formed,
wherein the first and the second waterproof members are attached onto the first and the second facing surfaces, respectively.

18. The electronic device of claim 12, further comprising:
a first sealing member provided on the first facing surface; and
a second sealing member corresponding to the first sealing member and provided on the second facing surface,
wherein the hydrophobic pattern is formed on respective facing surfaces of the first and the second sealing members.

19. The electronic device of claim 18, wherein the first and second facing surfaces comprise a first groove and a second groove, respectively, configured to accommodate respective first and second sealing members.

20. The electronic device of claim 18, further comprising a first waterproof member and a second waterproof member, the first and the second waterproof members respectively comprising a surface on which the hydrophobic pattern is formed,
wherein the first and the second waterproof members are attached onto the first and the second facing surfaces, respectively.
